(19) United States
(12) Patent Application Publication
(10) Pub. No.: US 2021/0240891 A1
(43) Pub. Date: Aug. 5, 2021

(54) AUTOMATIC TESTING TOOL FOR TESTING AUTONOMOUS SYSTEMS

(71) Applicant: North Carolina Agricultural and Technical State University, Greensboro, NC (US)

(72) Inventors: Ali Karimoddini, Greensboro, NC (US); Solomon Grebreyohannes, Greensboro, NC (US); Abdollah Homaifar, Greensboro, NC (US)

(21) Appl. No.: 17/148,909

(22) Filed: Jan. 14, 2021

Related U.S. Application Data
(60) Provisional application No. 62/961,023, filed on Jan. 14, 2020.

(51) Int. Cl. G06F 30/27; B60W 50/04; G06K 9/00; G06K 9/62

(52) U.S. Cl. CPC G06F 30/27; B60W 50/045; G06K 2209/21; G06K 9/6262; G06K 9/0063

(57) ABSTRACT

Methods and systems for virtually testing an autonomous vehicle. In some examples, a method includes receiving status reports from a simulated system of the autonomous vehicle for each of a number of simulated scenes. The method uses a fuzzy approximate reasoning to take system and environmental conditions into consideration to evaluate if mismatches with truth data are reasonable or not. The method includes outputting test results for the system of the autonomous vehicle by, for each of the simulated scenes, performing operations comprising: fuzzifying status parameters from the status report for the simulated scene into fuzzy input parameters; mapping the fuzzy input parameters through a set of rules for the system of the autonomous vehicle into fuzzy output parameters; and mapping the fuzzy output parameters into one or more crisp test result outputs.

### PRIORITY CLAIM

This application claims the priority benefit of U.S. Provisional Patent Application Ser. No. 62/961,023, filed Jan. 14, 2020, the disclosure of which is incorporated herein by reference in its entirety.

### STATEMENT OF GOVERNMENT INTEREST

This invention was made with government support under contract #W900KK-17-C-0002 awarded by the Department of Defense (DoD) Test Resource Management Center (TRMC) and the National Science Foundation (NSF) under award number 1832110. The government has certain rights in the invention.

### TECHNICAL FIELD

This specification relates generally to autonomous/semi-autonomous systems and in particular to testing autonomous/semi-autonomous vehicles such as unmanned aerial vehicles (UAVs), unmanned ground vehicles (UGVs), and autonomous/semi-autonomous cars.

### BACKGROUND

With advances in technologies, it is becoming possible to develop complex engineering systems with a high level of autonomy. Such “smart” systems can be developed using advanced sensing, perception, and control algorithms. All these engineered systems should be tested against requirements and specifications before being made operational. This leaves testers with significant challenges on how to test these complex intelligent autonomous systems, which often show dynamic and non-deterministic behaviors in different situations. The common practice is to design and conduct a set of experiments and create different scenarios by pushing the system to its end limits to evaluate the system's performance under different situations. Due to the safety concerns as well as time and cost constraints, the number of actual tests for an autonomous system e.g. an autonomous car or a UAV are limited. The richer the set of experiments and exposed conditions, the more reliable is the test process. To reduce risk and cost of actual test experiments, an alternative approach is to test an autonomous system and its autonomy and perception algorithms through a simulation environment, which makes it possible to run a large number of scenarios. The remaining challenge is then to check if the system under test (SUT) passes or fails the tests conducted over wide varieties of mission scenarios (possibly hundreds of thousands). On the other hand, the test results often cannot be simply determined by the comparison of the experiment/simulation results with a certain criterion/threshold, and usually require the tester to consider different conditions. For example, consider the perception algorithm of an autonomous car which should detect the traffic signs. This will require the tester to consider different system and environmental conditions such as the quality of the camera (its resolution), speed of the car, the visibility of the road, etc. It will be a cumbersome procedure, if not impossible, for a tester to check such a number of conducted tests and take into account all these system and environmental conditions.

### SUMMARY

This specification describes methods and systems for virtually testing an autonomous vehicle. In some examples, a method includes receiving status reports from a simulated system of the autonomous vehicle for each of a number of simulated scenes. The method includes outputting test results for the system of the autonomous vehicle by, for each of the simulated scenes, performing operations comprising: fuzzifying status parameters from the status report for the simulated scene into fuzzy input parameters; mapping the fuzzy input parameters through a set of rules for the system of the autonomous vehicle into fuzzy output parameters; and mapping the fuzzy output parameters into one or more crisp test result outputs.

The computer systems described in this specification may be implemented in hardware, software, firmware, or any combination thereof. In some examples, the computer systems may be implemented using a computer readable medium having stored thereon computer executable instructions that when executed by the processor of a computer control the computer to perform steps. Examples of suitable computer readable media include non-transitory computer readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

FIG. 1 is a block diagram illustrating a computer system configured for implementing the virtual tester;

FIG. 2 illustrates the data types communicated between the components of the system;

FIG. 3 is a block diagram illustrating the virtual tester;

FIG. 4 is a block diagram of an example fuzzy logic system;

FIG. 5 is a block diagram of the fuzzy inference engine;

FIG. 6 is a flow diagram illustrating an example method for testing an autonomous system;

FIG. 7 shows the general structure of the test result visualization;

FIG. 8 presents an example of explanation of test results and provides an insight into test results;

FIG. 9 shows the parallel processing scheme that is used for batch scenario testing; and

FIGS. 10A and 10B illustrate example graphical user interfaces.

### DETAILED DESCRIPTION

This specification describes methods and systems for testing autonomous systems. This specification describes a virtual tester, which replaces the human operator (tester) in the initial phases of processing of tests results by capturing his knowledge and incorporating it into the test process without requiring the human operator to actually involve in the initial phase of the process. As a result, tester can focus only on processed/refined test results. We use a Fuzzy Logic System to model the human knowledge as well as capturing the logistic uncertainty that exist during the modelling process. The automated tester can be used both for actual test experiments and in conjunction with a simulation environment; however, typically, the developed virtual tester is integrated with a simulation environment or a hardware in the loop simulator, which allows to test a system for a huge number of simulation runs. The Fuzzy Logic System captures the expert knowledge about the system and its expectation levels of performance, which then is used to compare the actual and truth data and judge/evaluate the mismatches, if any.

System Overview

Testing in simulation environment makes it possible to test autonomous systems, such as autonomous cars and UAVs, in a large number of possible scenarios. These days, there are a number of simulation tools that can conduct these simulations and generate test data. This specification describes an autonomous testing framework to use the generated simulation data to test a system.

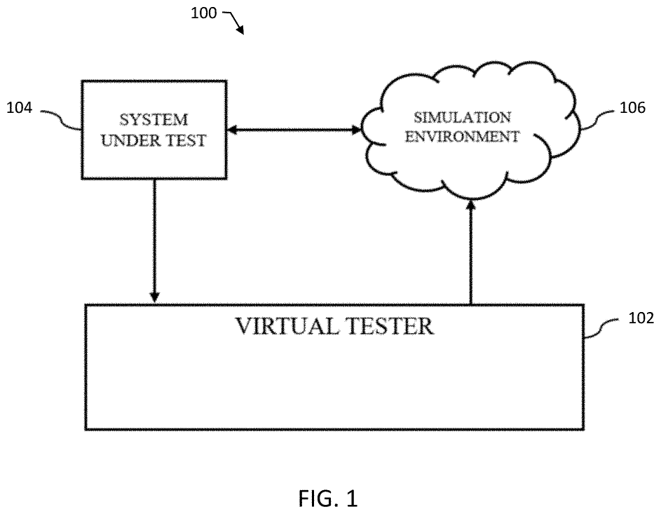

FIG. 1 is a block diagram illustrating a computer system 100 configured for implementing the virtual tester. The system 100 includes a virtual tester 102, a system under test (SUT) 104, and a simulation environment 106.

The SUT 104 can be, for example, the image-based target detection system of a UAV which is configured to detect a target. The simulation environment 106 is configured to generate a wide variety of mission scenarios. For example, for testing the image-based target detection of a UAV, a particular scenario may include a target at a certain location along with the flight simulation data and UAV reports about the detection of the target. The virtual tester 102 models the human tester activities and mimics the tester decision making whether a SUT passes or fails a test.

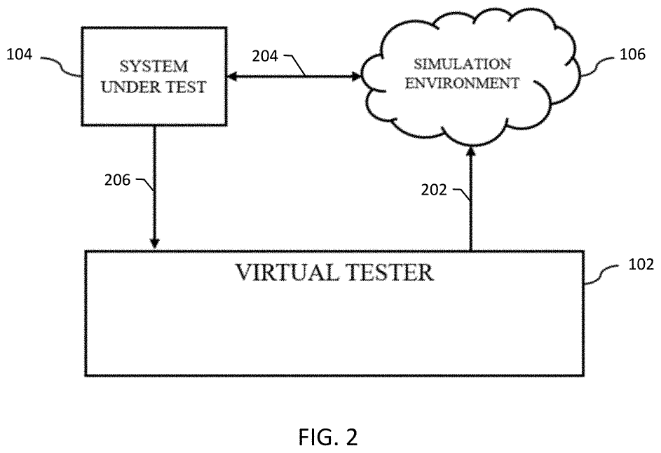

FIG. 2 illustrates the data types communicated between the components of the system 100. The data types include simulation environment parameters 202, scenes 204, and SUT reports 206.

The virtual tester 102 sets the simulation environment parameters 202 such as flight parameters, environmental factors, and geographical locations. For instance, for testing the image-based target detection of a UAV, the simulation environment parameters 202 can include UAV speed, UAV altitude, visibility of the environment, light level, and size of the target with respect to the size of field of view (FOV).

The simulation environment 106 generates different scenes 204 based on the simulation environment parameters 202. For instance, for testing the image-based target detection of a UAV, a particular scene includes the target at a particular location and the environmental conditions, over which the UAV flies to search for the target.

The SUT 104 reports, e.g., its status and perception in the SUT reports 206. For instance, for testing the image-based target detection of a UAV, the UAV reports whether a target is detected or not.

In some examples, the SUT 104 and the simulation environment 106 together form a hardware-in-the-loop (HIL) simulator. Various types of HIL simulators can be appropriate for the computer system 100.

Virtual Tester

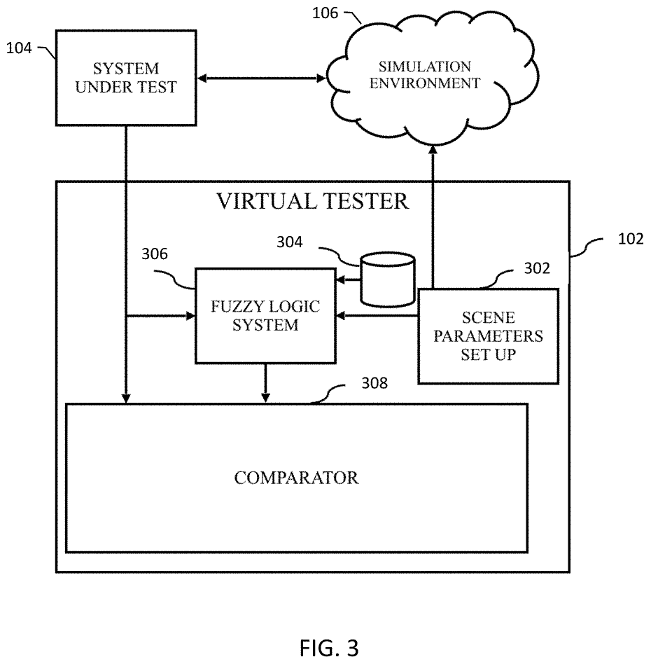

FIG. 3 is a block diagram illustrating the virtual tester 102. The virtual tester 102 includes a scene parameters set up block 302, a rule-based knowledge database 304, a fuzzy logic system 306, and a comparator 308.

The scene parameters set up block 302 generates the environment characteristics and flight parameters in which the SUT 104 operates within. For example, the following parameters can be used to characterize a scene:
Environment: visibility and light level
Target: target size
Flight specifics: flight altitude and speed

In some cases, all possible combinations of the parameters (resulted from a grid search) can be used in the test to cover all possible cases.

The rule-based knowledge database 304 contains a collection of “IF-THEN” statements using fuzzy terms. Rules model characteristics of the system can be based on experts' knowledge. The rules can be pre-programmed into the system from an outside source. For example, for testing the image-based target detection of a UAV, if we use five parameters, flight altitude, flight speed, light level, environment visibility, and imager characteristics (e.g., the size of the target with respect to the size of FOV), one of the rules may be:
“IF flight altitude is low and flight speed is fast and light level is dark and environment is haze, and ratio of size of target to FOV is small, THEN UAV does not have to detect the target based on experts' knowledge.”
   The rules are a set of tuples where each tuple represents a combination of the input parameters (‘IF’ part) and detection (‘THEN’ part). Typically, all combinations of the input parameters as expressed in the rules span all the possible cases. Hence, rules represent the SUT (UAV in this example) behavior for all cases.

Fuzzy Logic System

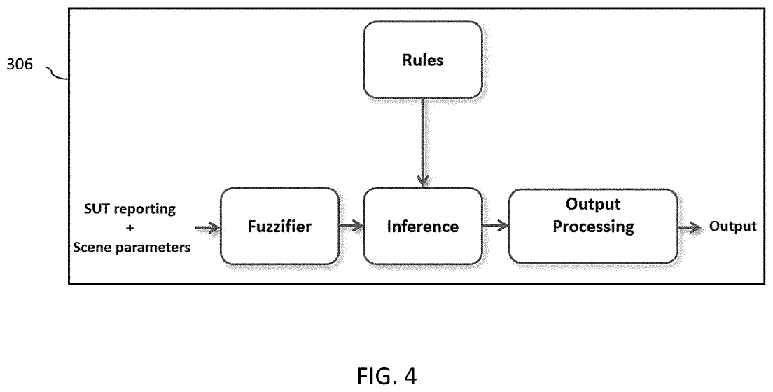

FIG. 4 is a block diagram of an example fuzzy logic system 306. The fuzzy logic system 306 is configured to determine whether the SUT 104 reports are reasonable, i.e., within expected boundaries, based on experts' knowledge or other outside sources. The fuzzy logic system 306 includes a fuzzifier, an inference block, and output processing.

The fuzzifier fuzzifies input parameters to handle uncertainty. This mimics how humans perceive parameters with relative terms. For example, for a RQ-11 Raven, a flight altitude of 700 ft AGL (Above Ground Level) is mapped into “Low” altitude or a flight speed of 100 kn (nautical mile per hour) is mapped into “Fast” speed. Similar fuzzy terms will be assigned for all input parameters and vehicle types.

In the fuzzy inference engine, fuzzy logic principles are used to map fuzzy input sets that flow through an IF-THEN rule (or a set of rules), into fuzzy output sets. Each rule is interpreted as a fuzzy implication.

Output processing comprises a defuzzifier that maps a fuzzy output of the inference engine to a crisp output (e.g., ‘1’ for the case that the UAV should detect the target if it is in FOV and ‘−1’ for the case that the UAV does not have to detect a target).

Mathematical Foundation of Fuzzy Logic System (FLS)

This section explains the mathematical background of the fuzzy logic system based on [1,2]. Here we consider the SUT perception as a simple binary classification. FIG. 4 presents a type-1 fuzzy logic system. Analysis is similar to other types of fuzzy logic systems. In some examples, multi-label fuzzy-based classification techniques can be used instead of binary classification.

Let X represent a set of p inputs of SUT and scene parameters, i.e., X={x₁, x₂, . . . , xₚ} and y is an output of the fuzzy system such as whether a target should have been detected (represented as ‘1’) or does not have to be detected (represented as ‘−1’).

The fuzzifier maps a crisp input x′ᵢ in X={x₁, x₂, . . . , xₚ} into a fuzzy value; i.e., it maps a specific value x′ into μ_{F}_{^{l}}_{ᵢ}(x′ᵢ)∈[0,1], where μ_{F}_{^{l}}_{ᵢ} represents the degree of belongness to membership function (MF) F^{l}ᵢ.

Rules are sets of IF-THEN statements that model the system. A rule R^{l}: A^{l}→G^{l} with A^{l}=F^{l}ᵢ× . . . ×F^{l}ₚ, can be represented as:

R^{l}: IF x₁ is F^{l}₁ and . . . ,xₚ is F^{l}ₚ, THEN y is G^{l}

where F^{l}ᵢ is the i^{th} antecedent (input) MF and G^{l} is the consequent (output) MF of the l^{th} rule.

For the consequent, crisp values +1 and −1 are used. For example, in the image-based detection of a target, +1 is used for ‘should detect the target if in FOV’ and −1 is used for ‘does not have to detect’.

y^{l}={1,detection and −1,non-detection}

Correspondingly, for the consequent sets, G^{l}, the MFs can be defined as

μ_{G}_{^{l}}={1 if y=y^{l} and 0 otherwise}

where y^{l} could be either +1 for ‘detection’ or −1 for ‘non-detection’.

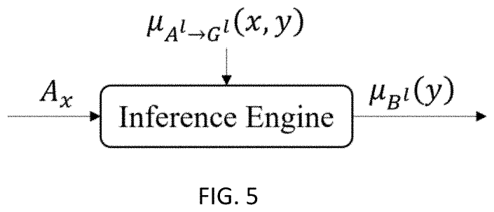

FIG. 5 is a block diagram of the fuzzy inference engine.

The membership function of each fired rule can be calculated using a t-norm as:

μ_{B}_{^{l}}(y)={T^{p}ᵢ₌₁μ_{F}_{^{l}}_{ᵢ}(xᵢ)=f^{l}(x),y=y^{l} and 0 otherwise}

where μ_{F}_{^{l}}_{ᵢ}(xᵢ), i=1, . . . , p, represents fuzzification values and T is a t-norm operation.

Using height defuzzification, the output using M rules can be calculated as

$$y ( x ) = \frac{{\sum }_{l = 1}^{M} {f}^{l} ( x ) {y}^{l}}{{\sum }_{i = 1}^{M} {f}^{l} ( x )} , {y}^{l} = \pm 1$$

A decision can be done based on

If y(x)>0, ‘detection’ and else ‘non-detection’.

The confidence level of the test results then can be captured as

$$c ( x ) = \frac{1 + \vert y ( x ) \vert}{2}$$

Comparator

The comparator 308 is configured to compare the truth data from the simulation environment, SUT, and the SUT reports taking into account the outputs of fuzzy logic system. For example, if there is a mismatch between the truth data and SUT output, then the virtual tester verifies if it is reasonable or the test has been failed. For this purpose, the virtual tester looks at the output of fuzzy logic system. If the fuzzy logic output is +1 the UAV should detect the target if it is in FOV and the mismatch is not acceptable. The complete logic of the comparator for a perception of an autonomous car/UAV on detecting a traffic sign or a target is shown in Table 1.

TABLE 1
Comparator's Logic

| | SUT Report | Simulation | | |
|---|---|---|---|---|
| | about detected | Environment | | |
| | sign or target | truth data | Virtual tester decision | SUT Test Result |
| 1 | Detected | Sign/target | No mismatch | Passed |
| 2 | Not Detected | Sign/target | Mismatch and Should | Failed |
| | | | be detected | (Miss detection) |
| 3 | Not Detected | Sign/target | Mismatch but | Passed |
| | | | reasonable to not | |
| | | | detect it | |
| 5 | Detected | No | Mismatch but | Passed |
| | | Sign/target | reasonable to falsely | |
| | | | detect it | |
| 6 | Detected | No | Mismatch and Should | Failed |
| | | Sign/target | not be detected | (False detection) |
| 7 | Not Detected | No | No mismatch | Passed |
| | | Sign/target | | |

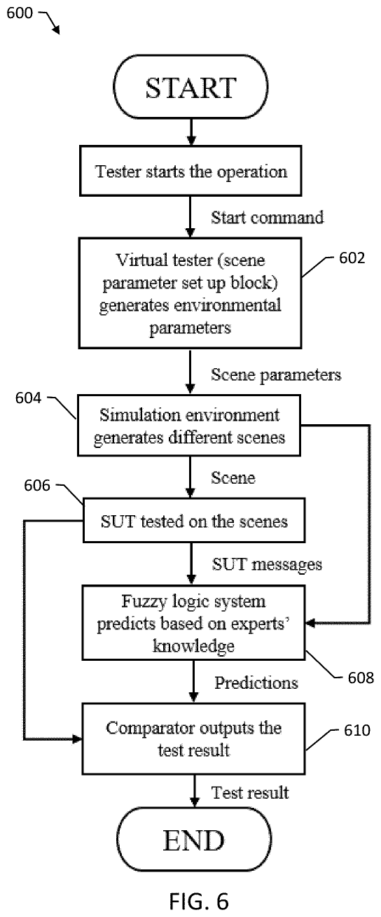

FIG. 6 is a flow diagram illustrating an example method 600 for testing an autonomous system. Method 600 includes generating environmental parameters by the virtual tester (602). Method 600 includes generating different scenes by the simulation environment (604). Method 600 includes testing the SUT on the scenes (606), predicting by the Fuzzy logic system based on experts' knowledge (608), and outputting a test result by the comparator (610).

A test report table is automatically generated as shown in Table 2. It provides a detailed explanation of the test along with a reason why car/UAV fails to detect. This includes test id and date, scenario type (that UAV was under test), test result, and the top rules fired with their firing strength. It hints the tester why car/UAV fails the test and how to retest for next phase.

TABLE 2
Test result report table

| | | | | SUT | | | | Test | |
|---|---|---|---|---|---|---|---|---|---|
| | | | | Report | Simulation | | | Result | |
| | | | | about | Environ- | | | Reason | |
| Test | Test | SUT | Scenario | detected | ment | Virtual | Test | (Rules | Firing |
| Id | Date | Id | Type | target | truth data | tester | Result | Fired) | Strength |
| T1_1 | 4/5/2019 | UAV1 | Scenario | Detected | Target | Should | Passed | Rule 7 | 83.65 |
| | 5:30:00 | | 1 | | Present | have | | Rule 6 | (Detected) |
| | | | | | | been | | Rule 9 | 6.27 |
| | | | | | | Detected | | | (Detected) |
| | | | | | | | | | 4.47 |
| | | | | | | | | | (Not |
| | | | | | | | | | Detected) |
| T1_2 | 4/5/2019 | UAV1 | Scenario | Detected | Target | Should | Passed | Rule 1 | 70.65 |
| | 7:30:00 | | 2 | | Present | have | | Rule 20 | (Detected) |
| | | | | | | been | | Rule 22 | 5.00 |
| | | | | | | Detected | | | (Detected) |
| | | | | | | | | | 3.28 |
| | | | | | | | | | (Detected) |

Test Results Analysis

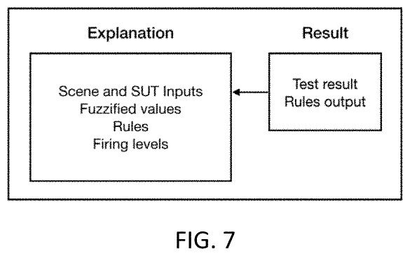

To analyze the test results, the tester needs to first check the report table. Tester can get a summary of the test. If tester further needs to know the reason of why SUT fails, he/she can examine the top fired rules. The test also provides a visualization that shows the inputs and their fuzzified values, rules and their firing level, which the determines the contribution of each rule to overall output, rule output (should have been detected/not detected), and the test results. FIG. 7 shows the general structure of the test result visualization. Unlike many machine learning techniques, which treat model as a black box, FLS provides an explanation or interpretation of the model result along with detailing the weight of contributing factors (inputs and rules).

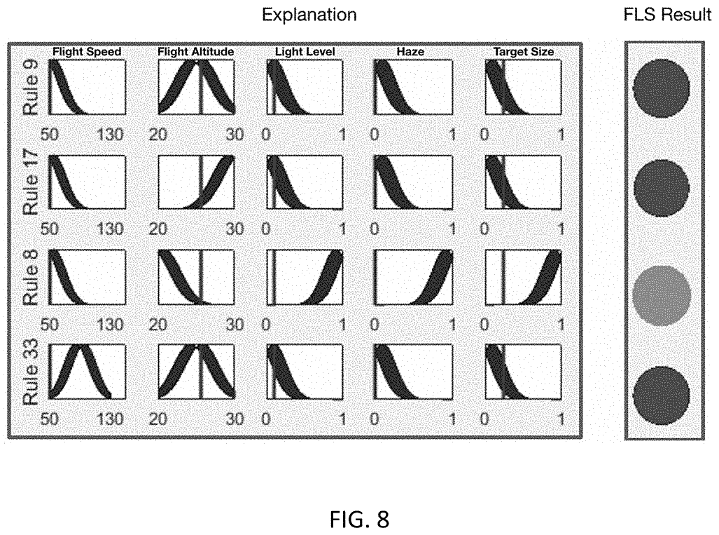

FIG. 8 presents an example of explanation of test results and provides an insight into test results. This example shows that mainly because of Rules 9 and 17 (since they are fired with high level of confidence) UAV does not have to detect target. The tester can then examine the explanation (left side of FIG. 8) relating the input parameters excitation in these rules to deduce to some conclusion (E.g., UAV was flying at high speed and far from target). Note that the fuzzified terms (e.g., ‘high’) are dependent on the SUT type and capabilities based on which the visualization of the input parameters and their fuzzified values are generated on the left sides of FIG. 8 for visualization purpose accordingly.

Parallel Processing

The test performed on a single case scenario can be extended for automatic testing for a batch of scenarios. Compared to single scenario testing, in batch testing, our aim is to test the system for all, or many, possible operation scenarios. For this purpose, we used Latin Hyper-Cube Sampling technique to generate different simulation parameters to fairly span the operation space and environment conditions. With the batch scenario testing, data parsing, pre-processing, and FLS processing are all performed automatically and in parallel.

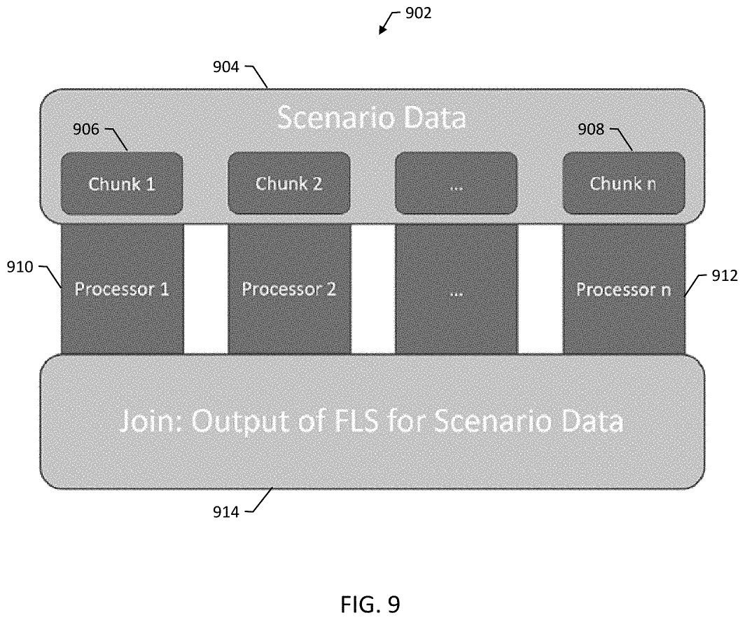

FIG. 9 shows the parallel processing scheme 902 that is used for the batch scenario testing. To handle a large number of processes under a batch scenario testing, we implemented parallel-processing schemes shown in FIG. 9. The batch scenario data 904 is first divided into smaller chunks (e.g., chunks 906 and 908) depending on the number of processors available. Each chunk is then assigned to a different processor (e.g., processors 910 and 912) for parallel processing.

Multiple processors execute FLS calculations simultaneously to reduce the overall processing time. The results of all processors are then joined and saved as output data 914. This is implemented using Python multiprocessing package calling our developed FLS calculations (implemented as a class), in which each processors executes the FLS class for each data chunk as a single job.

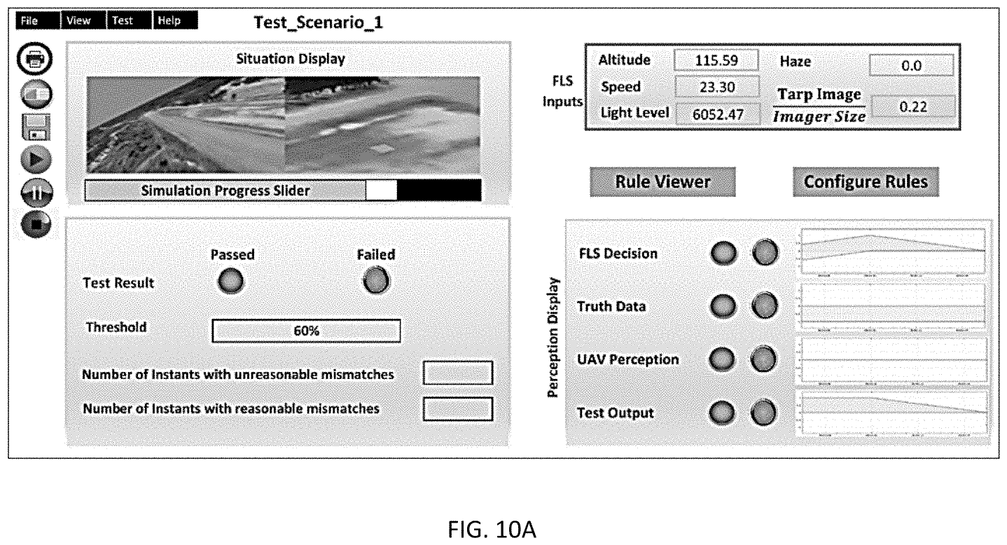

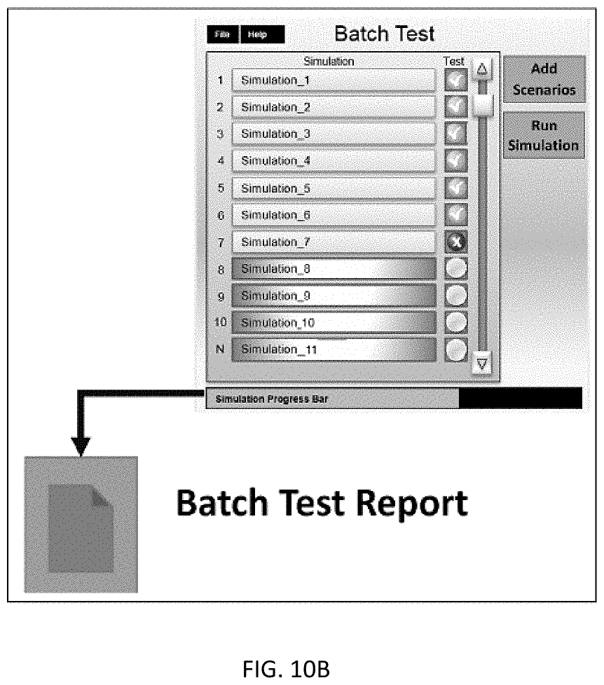

Further, the batch scenario testing process is aided by a Graphical User Interface (GUI) that can be used for scenario selection, input parameter modification, and output display. The GUI also presents the results/reports in an organized way so that the tester can access a summary report for the whole batch test as well as the results of individual test scenarios for further analysis using GUI. FIGS. 10A and 10B illustrate example GUIs for single scenario test results and batch scenario test results.

FIG. 10A shows the test result for a particular UAV flight test scenario named as Test Scenario 1. This interface provides options to load, save, print, play, pause and stop a simulation (here Test Scenario 1) using the respective display buttons. The top left part in FIG. 10A shows the situation display which can be moved forward/backward or paused by the simulation time progress slider. The bottom left part of FIG. 10A provides the test result for the simulation scenario (here Test Scenario 1). The test is displayed either as passed/failed if the number of unreasonable mismatch instants are lower/greater than a user specified threshold.

The bottom right window in FIG. 10A provides the perception display, showing the FLS Decision, Truth Data, UAV Perception, and Test Output values for the current test instant in the scenario. The top right part in FIG. 10A displays the respective values for the five FLS inputs for the current situation display of the UAV flight. Below the FLS inputs window, the user is provided with the options to view the FLS rules and to modify the rules.

FIG. 10B shows the Batch Test window that allows the user to run the simulation through the Graphical User Interface (GUI), add scenarios for testing, and monitor the test status of each processed scenario and the overall processing on the selected UAV flight test scenarios. A report of the Batch Test Results of the selected test scenarios is made available to the user for further analysis. Looking at the GUI window in FIG. 10B, we can see that Scenario 7 has failed, on which we can click to see the single scenario test results.

Although specific examples and features have been described above, these examples and features are not intended to limit the scope of the present disclosure, even where only a single example is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed in this specification (either explicitly or implicitly), or any generalization of features disclosed, whether or not such features or generalizations mitigate any or all of the problems described in this specification. Accordingly, new claims may be formulated during prosecution of this application (or an application claiming priority to this application) to any such combination of features. In particular, with reference to the appended claims, features from dependent claims may be combined with those of the independent claims and features from respective independent claims may be combined in any appropriate manner and not merely in the specific combinations enumerated in the appended claims.

### REFERENCES

[1] Timothy J. Ross, Fuzzy logic with engineering applications. John Wiley & Sons, 2005.
[2] Jerry M Mendel. Uncertain rule-based fuzzy logic systems: introduction and new directions. Springer, 2017.

What is claimed is:

1. A method for virtually testing an autonomous vehicle, the method comprising:
receiving, at a virtual tester implemented on a computer system comprising one or more processors, one or more status reports from a simulated system of the autonomous vehicle for each simulated scene of a plurality of simulated scenes; and
outputting, from the virtual tester, one or more test results for the system of the autonomous vehicle by, for each of the simulated scenes, performing operations comprising:
fuzzifying one or more status parameters for the simulated scene into one or more fuzzy input parameters;
mapping the fuzzy input parameters through a set of rules for the system of the autonomous vehicle into one or more fuzzy output parameters;
mapping the fuzzy output parameters into one or more crisp test result outputs;
comparing the status reports with simulation scene truth data and identifying mismatches; and
outputting test results based on evaluating the mismatches and mapping the fuzzy output parameters.

2. The method of claim 1, wherein mapping the fuzzy input parameters from the status report for the simulated scene into one or more fuzzy output parameters comprises accessing a rule-based knowledge database comprising a collection of IF-THEN statements using a plurality of fuzzy terms.

3. The method of claim 2, wherein outputting the one or more test results for the system of the autonomous vehicle comprises outputting a test report table specifying one or more of the top rules from the set of rules accessed in producing the test results.

4. The method of claim 1, wherein outputting the one or more test results for the system of the autonomous vehicle comprises comparing the crisp test result outputs with truth data and outputting a confidence level of the test results.

5. The method of claim 4, wherein outputting the one or more test results for the system of the autonomous vehicle comprises outputting a pass or a fail for the system of the autonomous vehicle based on comparing the crisp test result outputs with the truth data.

6. The method of claim 1, comprising setting, at the virtual tester, one or more simulation environment parameters of a simulation environment.

7. The method of claim 6, comprising causing, at the virtual tester, the simulation environment to generate the plurality of simulated scenes based on the simulation environment parameters and to simulate the system of the autonomous vehicle in each of the simulated scenes.

8. The method of claim 7, wherein the system of the autonomous vehicle is an image-based target detection system configured to detect a target.

9. The method of claim 8, wherein the simulated scenes include the target at different locations, and wherein the status reports from image-based target detection system specify whether or not the image-based target detection system detected the target.

10. The method of claim 8, wherein the simulation environment parameters include one or more of: autonomous vehicle speed, autonomous vehicle altitude, a visibility of the environment, a light level, and a size of the target with respect to a size of field of view (FOV).

11. A system for virtually testing an autonomous vehicle, the system comprising:
one or more processors and memory storing executable instructions for the one or more processors; and
a virtual tester implemented using the one or more processors, wherein the virtual tester is configured for:
receiving one or more status reports from a simulated system of the autonomous vehicle for each simulated scene of a plurality of simulated scenes; and
outputting one or more test results for the system of the autonomous vehicle by, for each of the simulated scenes, performing operations comprising:
fuzzifying one or more status parameters from the status report for the simulated scene into one or more fuzzy input parameters;
mapping the fuzzy input parameters through a set of rules for the system of the autonomous vehicle into one or more fuzzy output parameters; and
mapping the fuzzy output parameters into one or more crisp test result outputs.

12. The system of claim 11, wherein mapping the fuzzy input parameters from the status report for the simulated scene into one or more fuzzy output parameters comprises accessing a rule-based knowledge database comprising a collection of IF-THEN statements using a plurality of fuzzy terms.

13. The system of claim 12, wherein outputting the one or more test results for the system of the autonomous vehicle comprises outputting a test report table specifying one or more of the top rules from the set of rules accessed in producing the test results.

14. The system of claim 11, wherein outputting the one or more test results for the system of the autonomous vehicle comprises comparing the crisp test result outputs with truth data.

15. The system of claim 14, wherein outputting the one or more test results for the system of the autonomous vehicle comprises outputting a pass or a fail for the system of the autonomous vehicle based on comparing the crisp test result outputs with the truth data.

16. The system of claim 11, the operations comprising setting, at the virtual tester, one or more simulation environment parameters of a simulation environment.

17. The system of claim 16, the operations comprising causing, at the virtual tester, the simulation environment to generate the plurality of simulated scenes based on the simulation environment parameters and to simulate the system of the autonomous vehicle in each of the simulated scenes.

18. The system of claim 17, wherein the system of the autonomous vehicle is an image-based target detection system configured to detect a target.

19. The system of claim 18, wherein the simulated scenes include the target at different locations, and wherein the status reports from image-based target detection system specify whether or not the image-based target detection system detected the target.

20. The system of claim 18, wherein the simulation environment parameters include one or more of: autonomous vehicle speed, autonomous vehicle altitude, a visibility of the environment, a light level, and a size of the target with respect to a size of field of view (FOV).

21. A non-transitory computer readable medium comprising computer executable instructions embodied in the non-transitory computer readable medium that when executed by at least one processor of at least one computer cause the at least one computer to perform steps comprising:
receiving, at a virtual tester implemented on a computer system comprising one or more processors, one or more status reports from a simulated system of the autonomous vehicle for each simulated scene of a plurality of simulated scenes; and
outputting, from the virtual tester, one or more test results for the system of the autonomous vehicle by, for each of the simulated scenes, performing operations comprising:
fuzzifying one or more status parameters from the status report for the simulated scene into one or more fuzzy input parameters;
mapping the fuzzy input parameters through a set of rules for the system of the autonomous vehicle into one or more fuzzy output parameters; and
mapping the fuzzy output parameters into one or more crisp test result outputs.
